(19) United States
(12) Patent Application Publication
(10) Pub. No.: US 2009/0003463 A1
(43) Pub. Date: Jan. 1, 2009

(54) OUTPUT BUFFER CIRCUIT, SIGNAL TRANSMISSION INTERFACE CIRCUIT AND APPARATUS

(76) Inventors: Satoshi Muraoka, Yokohama (JP); Norio Chujo, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/099,953

(22) Filed: Apr. 9, 2008

(30) Foreign Application Priority Data
Apr. 9, 2007 (JP) 2007-101494

(51) Int. Cl. H04B 3/00; H03K 19/0175

(52) U.S. Cl. 375/257

(57) ABSTRACT

An output buffer circuit which transmits a logic signal to a transmission line includes a transmission pre-emphasis output circuit and a transmission pre-emphasis amount determination circuit. The transmission pre-emphasis output circuit controls a pre-emphasis amount according to an output signal from the transmission pre-emphasis amount determination circuit. The transmission pre-emphasis amount determination circuit adjusts a pre-emphasis amount and the number of pre-emphasis taps according to a pseudo loss control signal, controls a pre-emphasis amount of a transmission signal so that a signal amplitude is made smaller in a signal component with a high frequency than that of a signal component with a low frequency, and imparts signal degradation to a received waveform to realize transmission loss in a pseudo manner.

### CROSS-REFERENCE TO RELATED APPLICATION

The present application claims priority from Japanese Patent Application No. JP 2007-101494 filed on Apr. 9, 2007, the content of which is hereby incorporated by reference into this application.

### TECHNICAL FIELD OF THE INVENTION

The present invention relates to an output buffer circuit which transmits a logic signal to a transmission line, and in particular, to an effective technique applied to a high-speed signal transmission interface circuit and apparatus which are each provided with an output buffer circuit having a function of applying pre-emphasis to a transmission output waveform.

### BACKGROUND OF THE INVENTION

Electronic circuit apparatuses have improved their operation speed year by year, and research and development for realizing an electronic circuit apparatus with a faster operation speed have been actively conducted. If speed-up of the electronic circuit apparatus is realized, such a convenience is brought that, for example, some processings which conventionally required much time can be performed in a shorter time, or some processings thought to be impossible can be possible. Speed-up of the electronic circuit apparatus reduces costs of processing, and contributes to improvement of services in the world. Further, the industrial world will be stimulated by manufacturing such an excellent apparatus.

In order to realize speed-up of the electronic circuit apparatus, a demand for speed-up of data transmission signal between LSI internal circuits, between LSIs, between printed circuit boards, between apparatuses, between chassis, or the like, which are constituent elements for the electronic circuit apparatus, is increased.

As one of speed-up techniques for data transmission, for example, as a technique described in Japanese Patent Application Laid-open Publication No. 2003-309461 (Patent Document 1), an output buffer circuit having a pre-emphasis function of increasing a signal amplitude of a high frequency component of the signal, or decreasing a signal amplitude of a low frequency component thereof is provided in a practical use in order to compensate for signal decay of a transmission line typified by an LSI internal wire, an LSI package wire, a printed circuit board wire, a cable, a connector, and the like.

### SUMMARY OF THE INVENTION

In the technique described in Patent Document 1, as a premise of technique to the present invention, a configuration diagram of an output buffer circuit and a timing chart of an operation of the output buffer circuit are described with reference to FIG. 6 and FIG. 7, respectively.

The output buffer circuit shown in FIG. 6 comprises an inverter, a delay circuit, a buffer, and a tri-state buffer, and outputs a transmission signal from an output terminal to a transmission line when a data signal is inputted thereto. The transmission line is connected to a terminal voltage Vt via a terminal resistance Rt at a receiving end. The terminal resistance Rt is set to be equal to a characteristic impedance of the transmission line not to generate a reflected wave due to impedance mismatch.

The inverter is inputted with the data signal to output an inversion signal. The delay circuit is inputted with the data signal to output a delayed signal which is delayed by one cycle of data. The buffer is inputted with the inversion signal to output the transmission signal to an output terminal.

In the buffer, a P-type transistor 101 and an N-type transistor 102 operate in a complementary manner, and the P-type transistor 101 and the N-type transistor 102 have an equivalent ON-resistance Ra. The tri-state buffer is inputted with the inversion signal of the data signal and the delayed signal, and outputs the transmission signal to the output terminal. In the tri-state buffer, a P-type transistor 103 and an N-type transistor 106 are inputted with the delayed signal of the data signal, and operate in a complementary manner. A P-type transistor 104 and an N-type transistor 105 are inputted with the inversion signal of the data signal, and operate in a complementary manner. Thus, when the inversion signal and the delayed signal have the same logic value, the tri-state buffer outputs an inversion logic value of the same logic value, but when having different logic values, the tri-state buffer is made to be in an OFF state not to drive the output terminal. A serial synthetic resistance value of ON-resistances of the P-type transistor 103 and the P-type transistor 104 and a serial synthetic resistance value of ON-resistances of the N-type transistor 105 and the N-type transistor 106 have an equivalent ON-resistance value Rb.

In the timing chart shown in FIG. 7, at a timing T1, the data signal shifts from a low level to a high level, the inversion signal shifts to a low level, and the delayed signal remains in a low level. The P-type transistor 101 of the buffer, and the P-type transistors 103 and 104 of the tri-state buffer are respectively turned ON, while the other transistors are in an OFF state. At this time, an output voltage of the output signal becomes Voh1. The same manner is applied at a timing T7 and T9.

At a timing T2, The data signal remains in the high level, the inversion signal remains in the low level, and the delayed signal shifts from the low level to a high level. The P-type transistor 101 of the buffer, and the P-type transistor 104 and the N-type transistor 106 of the tri-state buffer are respectively turned ON, while the other transistors are in the OFF state. The tri-state buffer is made to be in the OFF state and the output voltage of the transmission signal becomes Voh2. The same manner is applied at a timing T3 and T10.

At a timing T4, The data signal shifts from the high level to the low level, the inversion signal shifts from the low level to the high level, and the delayed signal remains in the high level. The N-type transistor 102 of the buffer, and the N-type transistors 105 and 106 of the tri-state buffer are respectively turned ON, while the other transistors are in the OFF state. At this time, the output voltage of the transmission signal becomes Vol1. The same manner is applied at a timing T8 and T11.

At a timing T5, The data signal remains in the low level, the inversion signal remains in the high level, and the delayed signal shifts from the high level to the low level. The N-type transistor 102 of the buffer, and the N-type transistor 105 and the P-type transistor 104 of the tri-state buffer are respectively turned ON, while the other transistors are in the OFF state. The tri-state buffer is made to be in the OFF state, and the output voltage of the transmission signal becomes Vol2. The same manner is applied at a timing T6 and T12.

Thus, in the example of the output buffer circuit which is the premise of technique to the present invention, the output voltage of the transmission signal at the output terminal becomes the output voltages Voh1 and Vol1 during only one cycle when the data signal changes, and the output voltage becomes the output voltages Voh2 and Vol2 at the other timings, so that a pre-emphasis function of increasing a signal amplitude of a high frequency component of a signal or decreasing a signal amplitude of a low frequency component thereof is realized in order to compensate for signal decay of the transmission line.

Here, the above-mentioned premise of technique to the present invention increases a signal amplitude of a high frequency component of a signal or decreases a signal amplitude of a low frequency component thereof in order to compensate for signal decay of a transmission line. Accordingly, in the case where a wire length is short and loss of the wire is small, waveform quality of a signal inputted into a receiving circuit is excellent like an eye pattern 21 of a reception signal at the time of an normal operation shown in FIG. 4A. However, a signal waveform which has larger transmission loss and is poorer in quality is required for a test of the receiving circuit. For that reason, in order to confirm performance of a receiving circuit, it is necessary to conduct a test in an actual state of using an LSI, namely, in a state where a board, a cable, and a connector having a transmission loss close to an actual use transmission loss are connected.

The present invention has been made in view of these circumstances. An object of the present invention is to provide an output buffer circuit in which a performance test of a receiving circuit is conducted in a state of an LSI alone or in a state where a short wire is connected by adjusting an adjustable pre-emphasis amount of the output buffer circuit having a pre-emphasis function to realize pseudo transmission loss in an actual use state.

The above and other objects and novel characteristics of the present invention will be apparent from the description of the present specification and the accompanying drawings.

### SUMMARY OF THE INVENTION

The typical ones of the inventions disclosed in the present application will be briefly described as follows.

An output buffer circuit according to the present invention is an output buffer circuit having a pre-emphasis function and transmitting a logic signal to a transmission line, and comprises a transmission pre-emphasis output circuit and a transmission pre-emphasis amount determination circuit. The transmission pre-emphasis output circuit controls a pre-emphasis amount according to an output signal from the transmission pre-emphasis amount determination circuit. The transmission pre-emphasis amount determination circuit adjusts the pre-emphasis amount and the number of pre-emphasis taps according to a pseudo loss control signal, and controls the pre-emphasis amount of a transmission signal so that a signal amplitude of a signal component with a high frequency is made smaller than that of a signal component with a low frequency, thereby imparting signal degradation to a received waveform to realize transmission loss in a pseudo manner.

An effect obtained by the typical one of the inventions disclosed in the present application will be briefly described below.

According to the present invention, since transmission loss can be realized in the pseudo manner by imparting signal degradation to the received waveform, it becomes possible to conduct the performance test of the receiving circuit in a state of an LSI alone or in a state where a short wire is connected.

### BRIEF DESCRIPTIONS OF THE DRAWINGS

FIG. 1 is a configuration diagram showing a high-speed signal transmission interface circuit according to a first embodiment of the present invention;

FIG. 2 is a configuration diagram showing an output buffer circuit in detail according to the first embodiment of the present invention;

FIG. 3 is a timing chart showing an operation of the high-speed signal transmission interface circuit according to the first embodiment of the present invention;

FIG. 4A is an explanatory diagram showing a reception signal waveform at a time of a normal operation according to the first embodiment of the present invention;

FIG. 4B is an explanatory diagram showing a reception signal waveform at a time of a pseudo loss insertion according to the first embodiment of the present invention;

FIG. 5 is a configuration diagram showing a high-speed signal transmission interface circuit according to a second embodiment of the present invention;

FIG. 6 is a configuration diagram showing an output buffer circuit which is a premise of technique to the present invention; and

FIG. 7 is a timing chart showing an operation of the output buffer circuit which is the premise of technique to the present invention.

### DESCRIPTIONS OF THE PREFERRED EMBODIMENTS

Hereinafter, embodiments of the present invention will be described in detail with reference to the accompanying drawings. Note that, the same members are denoted by the same reference numerals throughout the drawings for describing the embodiments in principle, and repetitive description thereof will be omitted.

The embodiments according to the present invention realizes that, according to the pseudo loss control signal, the pre-emphasis amount and the number of pre-emphasis taps are adjusted, and the pre-emphasis amount of a transmission signal is controlled so that a signal amplitude of a signal component with a high frequency is made smaller than that of a signal component with a low frequency, and transmission loss is realized in the pseudo manner by imparting signal degradation to the received waveform.

### First Embodiment

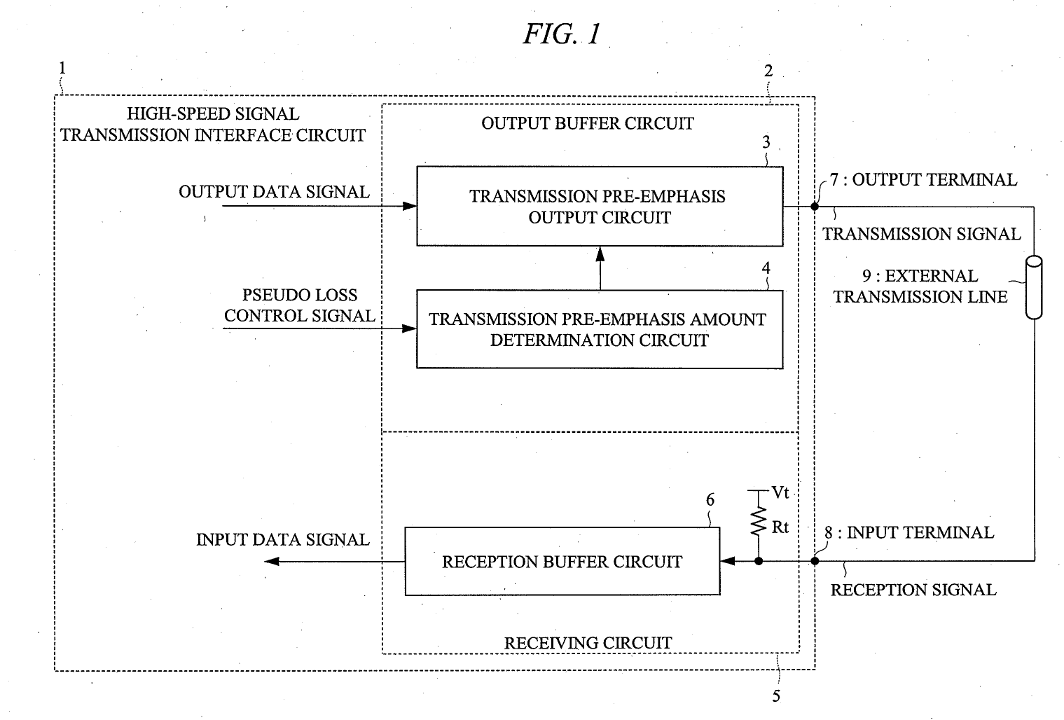

FIG. 1 is a configuration diagram showing a high-speed signal transmission interface circuit according to a first embodiment of the present invention. A high-speed signal transmission interface circuit 1 according to the first embodiment includes an output buffer circuit 2, a receiving circuit 5, and the like, where these circuits are integrally configured on the same LSI. An external transmission line 9 is connected between an output terminal 7 of the output buffer circuit 2 and an input terminal 8 of the receiving circuit 5 so that the high-speed signal transmission interface circuit 1 constitutes a high-speed signal transmission interface apparatus.

The output buffer circuit 2 is a circuit transmitting a logic signal to the external transmission line 9, and is configured by a transmission pre-emphasis output circuit 3, a transmission pre-emphasis amount determination circuit 4, and the like.

The transmission pre-emphasis output circuit 3 is a circuit being inputted with an output data signal, and controls a pre-emphasis amount according to an output signal from the transmission pre-emphasis amount determination circuit 4, and outputs a transmission signal.

The transmission pre-emphasis amount determination circuit 4 is a circuit adjusting the pre-emphasis amount and the number of pre-emphasis taps according to a pseudo loss control signal, and controls the pre-emphasis amount of the transmission signal so that a signal amplitude of a signal component with a high frequency is made smaller than that of a signal component with a low frequency to output to the transmission pre-emphasis output circuit 3.

The receiving circuit 5 is configured by a reception buffer circuit 6, a terminal resistor Rt connected to a terminal voltage Vt, and the like. The receiving circuit 5 is a circuit in which a reception signal is inputted thereto, and received by the reception buffer circuit 6 to output an input data signal.

In the high-speed signal transmission interface circuit 1 configured in the above manner, the output buffer circuit 2 is inputted with the output data signal to output the transmission signal to the external transmission line 9 connected to the output terminal 7. The transmission signal is an input into the receiving circuit 5 via the external transmission line 9, and the receiving circuit 5 outputs the input data signal.

The external transmission line 9 is connected to the terminal voltage Vt via the terminal resistor Rt at the receiving circuit 5 as a reception end. The terminal resistor Rt has a impedance equal to a characteristic impedance of the external transmission line 9 so that a reflected wave due to impedance mismatching is prevented from occurring.

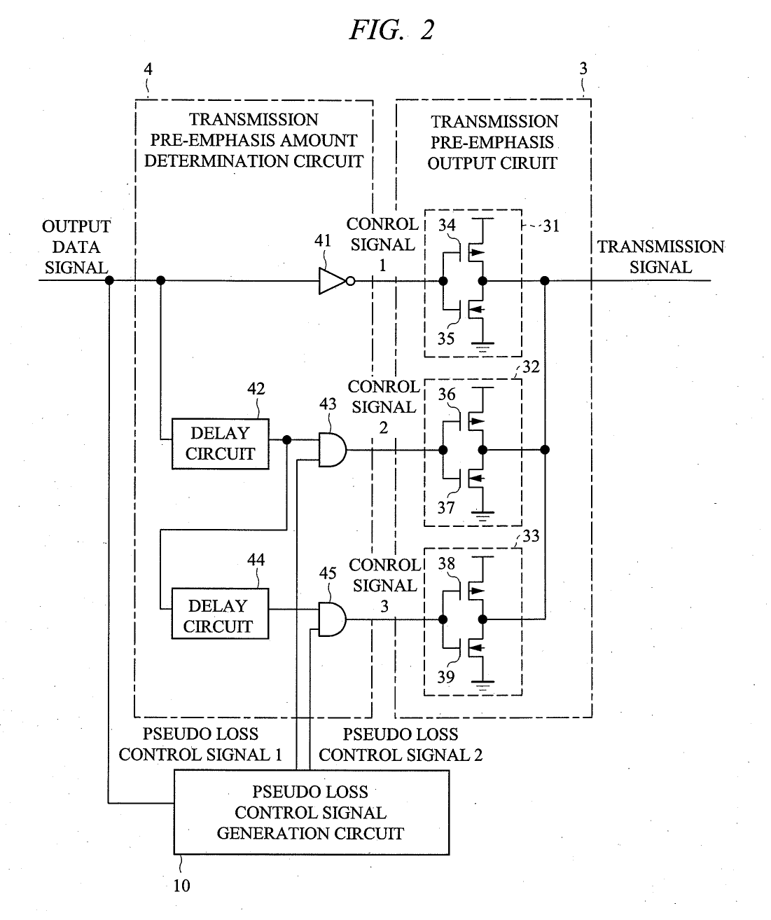

FIG. 2 is a configuration diagram showing the output buffer circuit 2 in detail. In the output buffer circuit 2, the transmission pre-emphasis output circuit 3 comprises three buffers 31, 32, and 33. These buffers 31, 32, and 33 comprise P-type transistors 34, 36, and 38 and N-type transistors 35, 37, and 39, respectively, where these transistors are connected to operate in a complementary manner. Input sides of the respective buffers 31, 32, and 33 are connected to the transmission pre-emphasis amount determination circuit 4, and control signals 1, 2, and 3 are respectively inputted thereto. Output sides of the respective buffers 31, 32, and 33 are connected to the output terminal 7 of the output buffer circuit 2 so that the transmission signal is outputted.

The transmission pre-emphasis amount determination circuit 4 comprises an inverter 41, delay circuits 42 and 44, and gate circuits 43 and 45. The inverter 41 is inputted with the output data signal, and an inverted control signal 1 is outputted from the inverter 41 to the buffer 31 of the transmission pre-emphasis amount determination circuit 4. The delay circuit 42 is inputted with the output data signal, and a delayed signal is inputted into the gate circuit 43 from the delay circuit 42. A logic operation between the delayed signal and a pseudo loss control signal 1 from a pseudo loss control signal generation circuit 10 is performed in the gate circuit 43, and a control signal 2 is outputted into the buffer 32 of the transmission pre-emphasis amount determination circuit 4. The delay circuit 44 is inputted with the delayed signal from the delay circuit 42, and the delayed signal from the delay circuit 44 is inputted into the gate circuit 45. A logic operation between the delayed signal and a pseudo loss control signal 2 from the pseudo loss control signal generation circuit 10 is performed in the gate circuit 45, and a control signal 3 is outputted into the buffer 33 of the transmission pre-emphasis amount determination circuit 4.

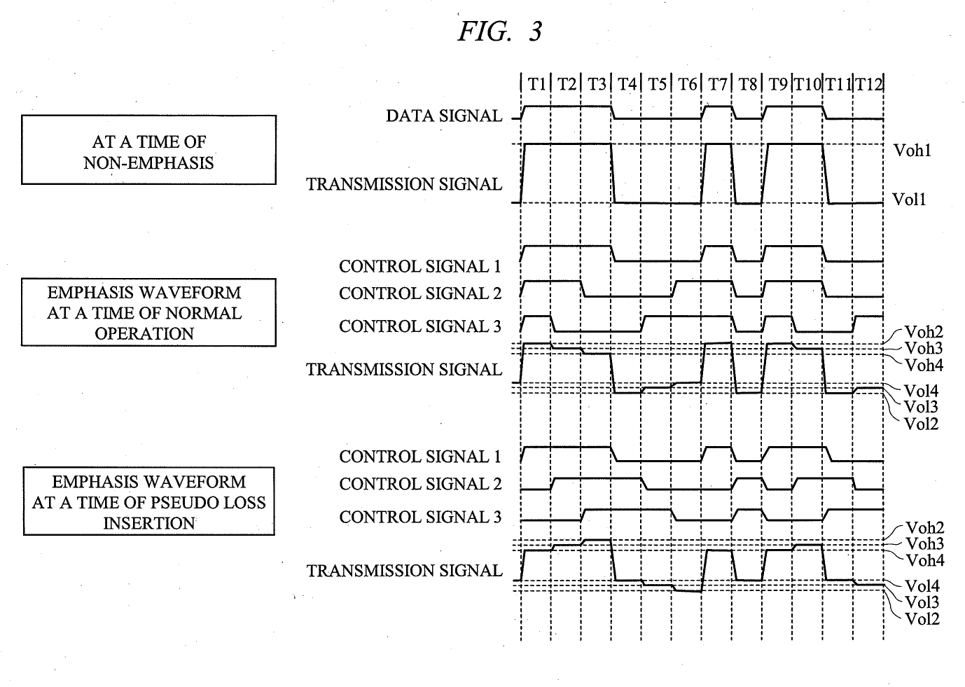

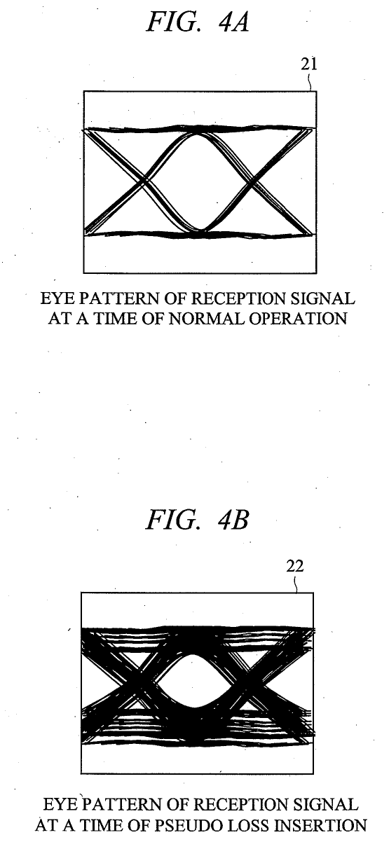

FIG. 3 is a timing chart showing an operation of the high-speed signal transmission interface circuit 1. Description is made with reference to reception signal waveforms shown in FIGS. 4A and 4B.

At a time of non-emphasis, when a data signal is in the high level (timings T1, T2, T3, T7, T9, and T10), an output voltage of a transmission signal becomes Voh1, and when the data signal is in the low level (timings, T4, T5, T6, T8, T11, and T12) the output voltage of the transmission signal becomes Vol1.

At a time of a normal operation, also at the timing T1, THE Data SIGNAL shifts from the low level to the high level, and the control signals 1, 2, and 3 to the buffers 31, 32, and 33 shift from a low level to a high level, respectively. At this time, the P-type transistors 34, 36, and 38 of the buffers 31, 32, and 33 are respectively turned ON, while the other transistors remain in the OFF state, so that the output voltage of the transmission signal becomes Voh2. The same manner is applied at the timing T7 and T9.

At the timing T2, the data signal remains in the high level, the control signals 1 and 2 to the buffers 31 and 32 remain in the high level, respectively, and the control signal 3 to the buffer 33 shifts from the high level to the low level. At this time, the P-type transistors 34 and 36 of the buffers 31 and 32, and the N-type transistor 39 of the buffer 33 are respectively turned ON, while the other transistors are in the OFF state, so that the output voltage of the transmission signal becomes Voh3. The same manner is applied at the timing T10.

At the timing T3, the data signal remains in the high level, the control signal 1 to the buffer 31 remains in the high level, the control signal 3 to the buffer 33 remains in the low level, and the control signal 2 to the buffer 32 shifts from the high level to the low level. At this time, the P-type transistor 34 of the buffer 31, and the N-type transistors 37 and 39 of the buffers 32 and 33 are respectively turned ON, while the other transistors are in the OFF state, so that the output voltage of the transmission signal becomes Voh4.

At the timing T4, the data signal shifts from the high level to the low level, the control signals 2 and 3 to the buffers 32 and 33 remain in the low level, respectively, and the control signal 1 to the buffer 31 shifts from the high level to the low level. At this time, the N-type transistors 35, 37 and 39 of the buffers 31, 32 and 33 are respectively turned ON, while the other transistors are in the OFF state, so that the output voltage of the transmission signal becomes Vol2. The same manner is applied at the timing T8 and T11.

At the timing T5, the data signal remains in the low level, the control signals 1 and 2 to the buffers 31 and 32 remain in the low level, respectively, and the control signal 3 to the buffer 33 shifts from the low level to the high level. At this time, the N-type transistors 35 and 37 of the buffers 31 and 32 and the P-type transistor 38 of the buffer 33 are respectively turned ON, while the other transistors are in the OFF state, so that the output voltage of the transmission signal becomes Vol3. The same manner is applied at the timing T12.

At the timing T6, the data signal remains in the low level, the control signal 1 to the buffer 31 remains in the low level, the control signal 3 to the buffer 33 remains in the high level, and the control signal 2 to the buffer 32 shifts from the low level to the high level. At this time, the N-type transistor 35 of the buffer 31, and the P-type transistors 36 and 38 of the buffers 32 and 33 are respectively turned ON, while the other transistors are in the OFF state, so that the output voltage of the transmission signal becomes Vol4.

with the manner described above, at a time of a normal operation, in order to compensate for signal decay of the external transmission line 9, a transmission signal waveform is made to realize a pre-emphasis waveform increasing a signal amplitude of a high frequency component of a signal or decreasing a signal amplitude of a low frequency component of a signal with respect to a data signal. In this case, as an eye pattern 21 shown in FIG. 4A, since the external transmission line 9 is short and has low loss, an eye waveform is excellent and has a large margin, so that this case cannot be applied to the performance inspection of the receiving circuit 5.

Therefore, at a time of a pseudo loss insertion, in a case of the performance inspection of the receiving circuit 5, also at the timing T1, the data signal shifts from the low level to the high level, the control signals 2 and 3 to the buffers 32 and 33 remain in the low level, and the control signal 1 to the buffer 31 shifts from the low level to the high level. At this time, the P-type transistor 34 of the buffer 31, and the N-type transistors 37 and 39 of the buffers 32 and 33 are turned ON, while the other transistors are in the OFF state, so that the output voltage of the transmission signal becomes Voh4. The same manner is applied at the timing T7 and T9.

At the timing T2, the data signal remains in the high level, the control signal 1 to the buffer 31 remains in the high level, the control signal 3 to the buffer 33 remains in the low level, and the control signal 2 to the buffer 32 shifts from the low level to the high level. At this time, the P-type transistors 34 and 36 of the buffers 31 and 32, and the N-type transistor 39 of the buffer 33 are respectively turned ON, while the other transistors are in the OFF state, so that the output voltage of the transmission signal becomes Voh3. The same manner is applied at the timing T10.

At the timing T3, the data signal remains in the high level, the control signals 1 and 2 to the buffers 31 and 32 remain in the high level, respectively, and the control signal 3 to the buffer 33 shifts from the low level to the high level. At this time, the P-type transistors 34, 36, and 38 of the buffers 31, 32, and 33 are respectively turned ON, while the other transistors are in the OFF state, so that the output voltage of the transmission signal becomes Voh2.

At the timing T4, the data signal shifts from the high level to the low level, the control signals 2 and 3 to the buffers 32 and 33 remain in the high level, respectively, and the control signal 1 to the buffer 31 shifts from the high level to the low level. At this time, the N-type transistor 35 of the buffer 31, and the P-type transistors 36 and 38 of the buffers 32 and 33 are respectively turned ON, while the other transistors are in the OFF state, so that the output voltage of the transmission signal becomes Vol4. The same manner is applied at the timing T8 and T11.

At the timing T5, the data signal remains in the low level, the control signal 1 to the buffer 31 remains in the low level, the control signal 3 to the buffer 33 remains in the high level, and the control signal 2 to the buffer 32 shifts from the high level to the low level. At this time, the N-type transistors 35 and 37 of the buffers 31 and 32, and the P-type transistor 38 of the buffer 33 are respectively turned ON, and the other transistors are in the OFF state, so that the output voltage of the transmission signal becomes Vol3. The same manner is applied at the timing T12.

At the timing T6, the data signal remains in the low level, the control signals 1 and 2 to the buffers 31 and 32 remain in the low level, and the control signal 3 to the buffer 33 shifts from the high level to the low level. At this time, the N-type transistors 35, 37, and 39 of the buffers 31, 32, and 33 are respectively turned ON, while the other transistors are in the OFF state, so that the output voltage of the transmission signal becomes Vol2.

with the manner described above, in the case of the performance inspection of the receiving circuit 5, an emphasis waveform at a time of a pseudo loss insertion decreases a signal amplitude of a high frequency component of a signal or increases a signal amplitude of a low frequency component of a signal in order to deteriorate an eye opening of the received waveform, so that a pre-emphasis waveform having the output voltage of the transmission signal of Voh2, Voh3, Voh4, Vol2, Vol3, or Vol4 is generated. In this case, as an eye pattern 22 shown in FIG. 4B, compensation for loss on the external transmission line 9 cannot be obtained, so the eye waveform deteriorates, and a margin of the receiving circuit 5 becomes small, whereby implementation of the performance inspection of the receiving circuit 5 is made possible.

As a result, according to the present embodiment, the pre-emphasis amount in a voltage value such as the output voltage Voh2, Voh3, Voh4, Vol2, Vol3, and Vol4, and the number of pre-emphasis taps based upon such a cycle as a one-cycle period, a two-cycle period, or a three-cycle period are adjusted according to the pseudo loss control signal, and the pre-emphasis amount of the transmission signal is controlled so that a signal amplitude of a signal component with a high frequency is smaller than that of a signal component with a low frequency. As a result, since transmission loss is realized in a pseudo manner by imparting signal degradation to the received waveform, the performance test of the receiving circuit 5 can be conducted in a state where a short wire such as the external transmission line 9 is connected.

Incidentally, in the present embodiment, the output buffer circuit of a single-end type has been shown, but a differential output buffer may be configured by two systems having the same output buffer circuit.

### Second Embodiment

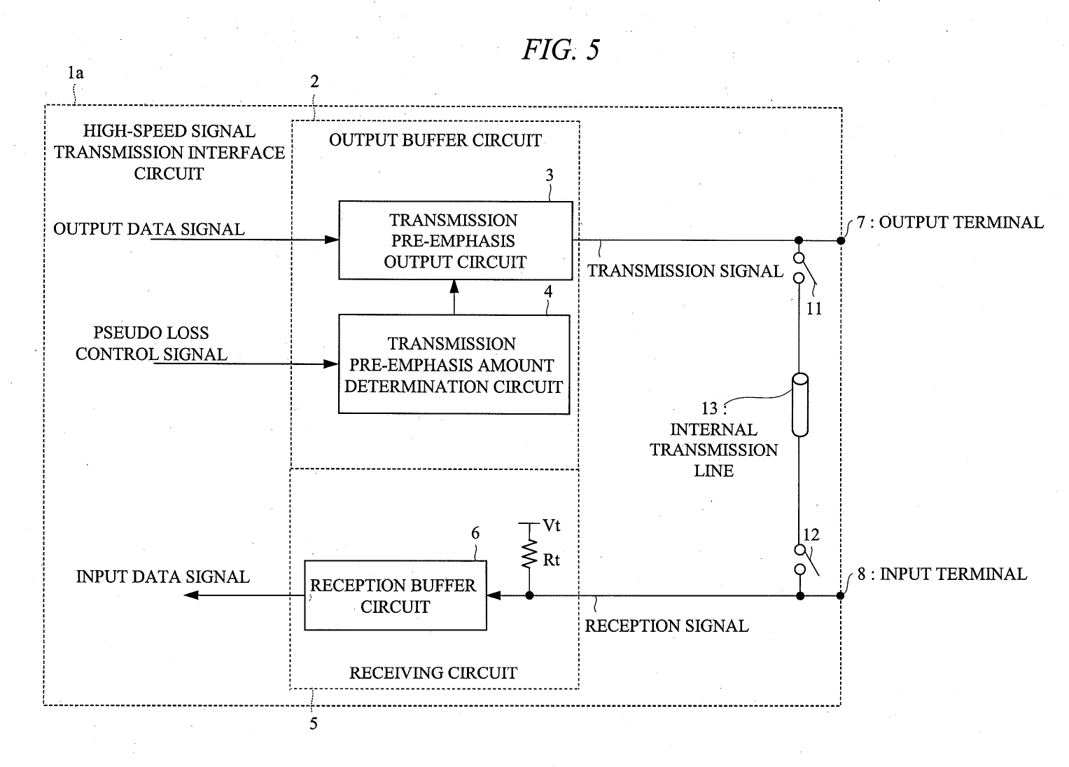

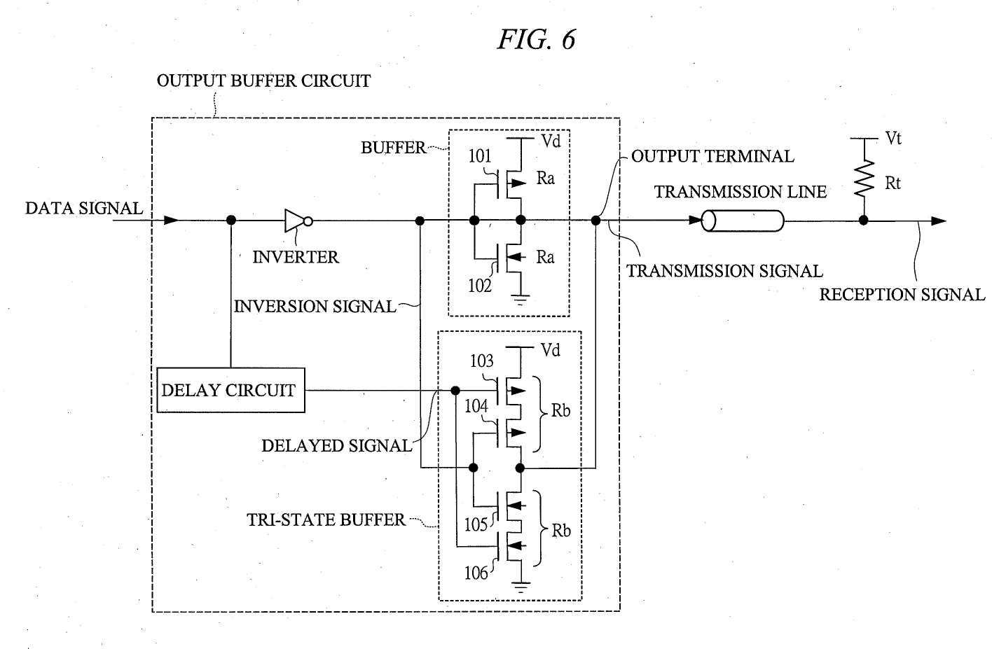

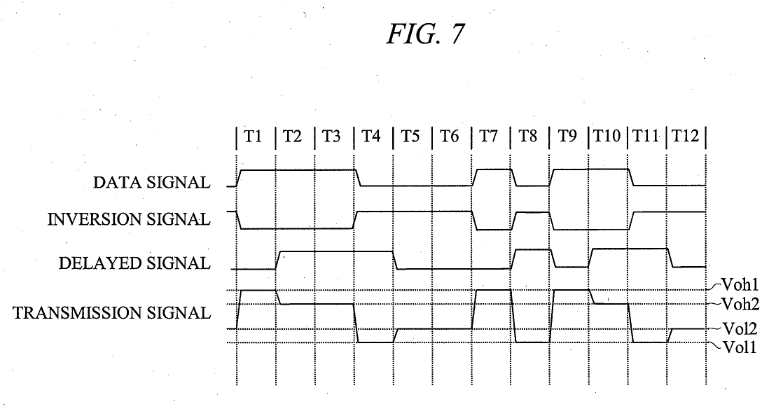

FIG. 5 is a configuration diagram showing a high-speed signal transmission interface circuit according to a second embodiment of the present invention. A high-speed signal transmission interface circuit 1a according to the second embodiment includes an internal transmission line 13 and the like in addition to the output buffer circuit 2 and the receiving circuit 5, where these members are integrally configured on the same LSI. In the high-speed signal transmission interface circuit 1a, the internal transmission line 13 is connected between the output terminal 7 of the output buffer circuit 2 and the input terminal 8 of the receiving circuit 5 via switches 11 and 12, so that a high-speed signal transmission interface apparatus is configured. Since configurations and functions of the respective circuits in the present embodiment are similar to those in the first embodiment, descriptions thereof are omitted herein.

Accordingly, like the present embodiment, in a configuration in which the output buffer circuit 2 and the receiving circuit 5 are connected through the switches 11, 12 and the internal transmission line 13 inside an LSI, as with the first embodiment, the pre-emphasis amount and the number of pre-emphasis taps are adjusted according to the pseudo loss control signal, and the pre-emphasis amount of the transmission signal is controlled so that a signal amplitude of a signal component with a high frequency is smaller than that of a signal component with a low frequency. Whereby transmission loss can be realized by imparting signal degradation to the received waveform in the pseudo manner, and the performance test of the receiving circuit 5 can be conducted with an LSI alone.

The invention which has been made by the present inventors has been concretely described above, but it is needless to say that the present invention is not limited to the embodiments, and it can be modified variously without departing from the gist of the invention.

The output buffer circuit of the present invention can be applied to applications for performing data transmission using a transmission line such as data transmission within an LSI constituting an electronic circuit apparatus, data transmission in a printed circuit board between LSIs, data transmission between printed circuit boards via a backplane or a connector, data transmission between printed circuit boards via a cable, and data transmission between apparatuses via a cable. In addition, since an output circuit of an LSI and a function of inspecting performances of a receiving circuit of the LSI are provided, the present invention can be applied to a semiconductor inspection apparatus.

What is claimed is:

1. An output buffer circuit transmitting a logic signal to a transmission line, comprising:
means for producing a waveform having at least four kinds of signal voltages at a transmission side according to a signal decay amount of the transmission line,
wherein, according to a pseudo loss control signal, a pre-emphasis amount and the number of pre-emphasis taps are adjusted; a pre-emphasis amount of a transmission signal is controlled so that a signal amplitude of a signal component with a high frequency is made smaller than that of a signal component with a low frequency; and transmission loss is realized in a pseudo manner by imparting signal degradation to a received waveform.

2. The output buffer circuit according to claim 1,
wherein the output buffer circuit is integrally configured with a receiving circuit.

3. The output buffer circuit according to claim 2,
wherein a transmission line connecting the output buffer circuit to the receiving circuit is integrally configured with the output buffer circuit and the receiving circuit.

4. The output buffer circuit according to claim 1, further comprising two systems of a first output buffer circuit and a second output buffer circuit,
wherein a differential output buffer is configured by the first output buffer circuit and the second output buffer circuit.

5. An output buffer circuit transmitting a logic signal to a transmission line, comprising:
a transmission pre-emphasis amount determination circuit adjusting a pre-emphasis amount and the number of pre-emphasis taps according to a pseudo loss control signal and controlling a pre-emphasis amount of a transmission signal so that a signal amplitude of a signal component with a high frequency is made smaller than that of a signal component with a low frequency; and
a transmission pre-emphasis output circuit controlling the pre-emphasis amount according to an output signal from the transmission pre-emphasis amount determination circuit.

6. A signal transmission interface circuit including an output buffer circuit transmitting a logic signal to a transmission line,
wherein the output buffer circuit comprises:
a transmission pre-emphasis amount determination circuit adjusting a pre-emphasis amount and the number of pre-emphasis taps according to a pseudo loss control signal and controlling a pre-emphasis amount of a transmission signal so that a signal amplitude of a signal component with a high frequency is made smaller than that of a signal component with a low frequency; and
a transmission pre-emphasis output circuit controlling the pre-emphasis amount according to an output signal from the transmission pre-emphasis amount determination circuit.

7. The signal transmission interface circuit according to claim 6, further comprising a receiving circuit,
wherein the output buffer circuit and the receiving circuit are configured on the same LSI.

8. The signal transmission interface circuit according to claim 7, further comprising a transmission line connecting the output buffer circuit to the receiving circuit,
wherein the output buffer circuit, the receiving circuit, and the transmission line are configured on the same LSI.

9. A signal transmission interface apparatus including a signal transmission interface circuit,
wherein the signal transmission interface circuit comprises an output buffer circuit transmitting a logic signal to a transmission line, and
the output buffer circuit comprises:
a transmission pre-emphasis amount determination circuit adjusting a pre-emphasis amount and the number of pre-emphasis taps according to a pseudo loss control signal and controlling a pre-emphasis amount of a transmission signal so that a signal amplitude of a signal component with a high frequency is made smaller than that of a signal component with a low frequency; and
a transmission pre-emphasis output circuit controlling the pre-emphasis amount according to an output signal from the transmission pre-emphasis amount determination circuit.
